(19) United States
(12) Patent Application Publication
(10) Pub. No.: US 2020/0184130 A1
(43) Pub. Date: Jun. 11, 2020

(54) Systems, Methods, and Apparatus for Simulation of Complex Subsurface Fracture Geometries Using Unstructured Grids

(71) Applicants: Sim Tech LLC, Katy, TX (US); Board of Regents, The University of Texas System, Austin, TX (US)

(72) Inventors: Kamy Sepehrnoori, Austin, TX (US); Yifei Xu, Houston, TX (US); Wei Yu, College Station, TX (US); Francisco Marcondes, Katy, TX (US); Jijun Miao, Katy, TX (US)

(73) Assignees: Sim Tech LLC, Katy, TX (US); Board of Regents, The University of Texas System, Austin, TX (US)

(21) Appl. No.: 16/700,128

(22) Filed: Dec. 2, 2019

Related U.S. Application Data
(60) Provisional application No. 62/776,644, filed on Dec. 7, 2018.

(51) Int. Cl. G06F 30/23; E21B 49/00; E21B 41/00; G01V 99/00

(52) U.S. Cl. CPC G06F 30/23; E21B 49/00; E21B 43/26; G01V 99/005; E21B 41/0092

(57) ABSTRACT

Systems and methods for simulating subterranean regions having multi-scale fracture geometries. Non-intrusive embedded discrete fracture modeling formulations are applied to two-dimensional and three-dimensional unstructured grids, with mixed elements, using an element-based finite-volume method in conjunction with commercial simulators to model subsurface characteristics in regions having complex hydraulic fractures, complex natural fractures, or a combination of both.

### CROSS REFERENCE TO RELATED APPLICATIONS

This application claims priority to U.S. Provisional Patent Application No. 62/776,644, filed on Dec. 7, 2018, titled “Systems, Methods, and Apparatus for Simulation of Complex Subsurface Fracture Geometries Using Unstructured Grids.” The entire disclosure of Application No. 62/776,644 is hereby incorporated herein by reference.

### FIELD OF THE INVENTION

The present disclosure relates generally to methods and systems for the simulation of subterranean regions with multi-scale complex fracture geometries, applying non-intrusive embedded discrete fracture modeling f combined with element-based finite-volume formulations.

### BACKGROUND

The recovery of natural resources (e.g., oil, gas, geothermal steam, water, coal bed methane) from subterranean formations is often made difficult by the nature of the rock matrix in which they reside. Some formation matrices have very limited permeability. Such “unconventional” subterranean regions include shale reservoirs, siltstone formations, and sandstone formations. Technological advances in the areas of horizontal drilling and multi-stage hydraulic fracturing have improved the development of unconventional reservoirs. Hydraulic fracturing is a well stimulation technique used to increase permeability in a subterranean formation. In the fracturing process, a fluid is pumped into casing lining the wellbore traversing the formation. The fluid is pumped in at high pressure to penetrate the formation via perforations formed in the casing. The high-pressure fluid creates fissures or fractures that extend into and throughout the rock matrix surrounding the wellbore. Once the fractures are created, the fluids and gases in the formation flow more freely through the fractures and into the wellbore casing for recovery to the surface.

Since the presence of fractures significantly impacts the flow behavior of subterranean fluids and gases, it is important to accurately model or simulate the geometry of the fractures in order to determine their influence on well performance and production optimization. A conventional method for simulation of fluid flow in fractured reservoirs is the classic dual-porosity or dual-permeability model. This dual-continuum method considers the fractured reservoir as two systems, a fracture system and a matrix system. This method is suitable to model small-scale fractures with a high density. It cannot handle large scale fractures like those created during hydraulic fracturing operations. In addition, this method cannot deal with fractures explicitly

Unstructured grids have been used in reservoir simulation. Compared to structured grids, unstructured grids offer the capability to represent irregular reservoir structures and reservoir boundaries, as they are more flexible regarding the geometry of gridblocks and their discretization. However, as the number and complexity of fractures increase, conventional unstructured gridding methods present complex gridding issues and an expensive computational cost. Conventional reservoir simulators using unstructured gridding are limited to vertical fractures. Thus, a need remains for improved techniques to efficiently and accurately simulate complex fracture geometries using unstructured grids.

### SUMMARY

According to an aspect of the invention, a method for simulating a subterranean region having fracture geometries is disclosed. In this embodiment, data representing a subterranean region is obtained, the data comprising a matrix grid and fracture parameters; elements in the matrix grid are divided into sub-elements; control volumes are determined using the sub-elements; transmissibility factors between fracture segments and the control volumes are determined; and a simulation of the subterranean region is generated using the transmissibility factors.

According to another aspect of the invention, a system for simulating a subterranean region having fracture geometries is disclosed. The system includes at least one processor; a memory linked to the processor, the memory having instructions stored therein, which when executed cause the processor to perform functions including to: input data representing a subterranean region, the data comprising a matrix grid and fracture parameters; divide elements in the matrix grid into sub-elements; determine control volumes using the sub-elements; determine transmissibility factors between fracture segments and the control volumes; and produce output values corresponding to the determined transmissibility factors for generation of a simulation of the subterranean region.

According to another aspect of the invention, a computer-readable medium is disclosed. The computer-readable medium embodies instructions which when executed by a computer cause the computer to perform a plurality of functions, including functions to: input data representing a subterranean region, the data comprising a matrix grid and fracture parameters; divide elements in the matrix grid into sub-elements; determine control volumes using the sub-elements; determine transmissibility factors between fracture segments and the control volumes; and produce output values corresponding to the determined transmissibility factors for generation of a simulation of the subterranean region.

### BRIEF DESCRIPTION OF THE DRAWINGS

The following figures form part of the present specification and are included to further demonstrate certain aspects of the present disclosure and should not be used to limit or define the claimed subject matter. The claimed subject matter may be better understood by reference to one or more of these drawings in combination with the description of embodiments presented herein. Consequently, a more complete understanding of the present embodiments and further features and advantages thereof may be acquired by referring to the following description taken in conjunction with the accompanying drawings, in which like reference numerals may identify like elements, wherein:

FIG. 1A, in accordance with some embodiments of the present disclosure, depicts a schematic of a subsurface physical domain representation using a formulation for handling complex fractures;

FIG. 1B, in accordance with some embodiments of the present disclosure, depicts a schematic of a computational domain using the formulation for handling the representation in FIG. 1A;

FIG. 2, in accordance with some embodiments of the present disclosure, depicts a schematic of a connection between a fracture cell and a matrix cell;

FIG. 3, in accordance with some embodiments of the present disclosure, depicts a 3D reservoir model matrix grid with an inclined fracture;

FIG. 4A, in accordance with some embodiments of the present disclosure, depicts a schematic of a fracture intersection with all subsegments having similar dimensions;

FIG. 4B, in accordance with some embodiments of the present disclosure, depicts a schematic of a fracture intersection with a high contrast between the subsegment areas;

FIG. 5, in accordance with some embodiments of the present disclosure, depicts a schematic of the modeling of a nonplanar fracture;

FIG. 6, in accordance with some embodiments of the present disclosure, depicts a 2D schematic of a fracture segment with varying aperture;

FIG. 7A, in accordance with some embodiments of the present disclosure, depicts a 2D schematic of small fracture segments in a matrix grid;

FIG. 7B, in accordance with some embodiments of the present disclosure, depicts another 2D schematic of small fracture segments in a matrix grid;

FIG. 8A depicts a two-dimensional mesh of an unstructured grid produced in accordance with some embodiments of the present disclosure;

FIG. 8B depicts another two-dimensional mesh of an unstructured grid produced in accordance with some embodiments of the present disclosure;

FIG. 9 depicts a schematic of a pyramid element in accordance with some embodiments of the present disclosure;

FIG. 10A depicts a three-dimensional grid with several types of elements in accordance with some embodiments of the present disclosure;

FIG. 10B depicts the discretization of the grid of FIG. 10A in accordance with some embodiments of the present disclosure;

FIG. 11A depicts a two-dimensional mesh of an unstructured grid produced in accordance with some embodiments of the present disclosure;

FIG. 11B depicts another a two-dimensional mesh of an unstructured grid produced in accordance with some embodiments of the present disclosure;

FIG. 11C depicts another a two-dimensional mesh of an unstructured grid produced in accordance with some embodiments of the present disclosure;

FIG. 11D depicts another a two-dimensional mesh of an unstructured grid produced in accordance with some embodiments of the present disclosure;

FIG. 12 depicts another a two-dimensional mesh of an unstructured grid produced in accordance with some embodiments of the present disclosure;

FIG. 13 depicts the three-dimensional grid of FIG. 10B produced in accordance with some embodiments of the present disclosure;

FIG. 14A depicts a three-dimensional grid with two fractures before a merging process in accordance with some embodiments of the present disclosure;

FIG. 14B depicts the grid of FIG. 14A after the merging process in accordance with some embodiments of the present disclosure;

FIG. 15, in accordance with some embodiments of the present disclosure, depicts a flow chart illustrating a process for simulating a subterranean region having fracture geometries;

FIG. 16, in accordance with some embodiments of the present disclosure, depicts a system for simulating subsurface regions with complex fracture geometries;

FIG. 17A depicts a coordinate mapping of a triangular element in accordance with some embodiments of the present disclosure;

FIG. 17B depicts a coordinate mapping of a quadrilateral element in accordance with some embodiments of the present disclosure;

FIG. 18A depicts a coordinate mapping of a tetrahedron element in accordance with some embodiments of the present disclosure;

FIG. 18B depicts a coordinate mapping of a prism element in accordance with some embodiments of the present disclosure;

FIG. 18C depicts a coordinate mapping of a hexahedron element in accordance with some embodiments of the present disclosure; and

FIG. 18D depicts a coordinate mapping of a pyramid element in accordance with some embodiments of the present disclosure.

### DETAILED DESCRIPTION

The foregoing description of the figures is provided for the convenience of the reader. It should be understood, however, that the embodiments are not limited to the precise arrangements and configurations shown in the figures. Also, the figures are not necessarily drawn to scale, and certain features may be shown exaggerated in scale or in generalized or schematic form, in the interest of clarity and conciseness.

While various embodiments are described herein, it should be appreciated that the present invention encompasses many inventive concepts that may be embodied in a wide variety of contexts. The following detailed description of exemplary embodiments, read in conjunction with the accompanying drawings, is merely illustrative and is not to be taken as limiting the scope of the invention, as it would be impossible or impractical to include all of the possible embodiments and contexts of the invention in this disclosure. Upon reading this disclosure, many alternative embodiments of the present invention will be apparent to persons of ordinary skill in the art. The scope of the invention is defined by the appended claims and equivalents thereof.

Illustrative embodiments of the invention are described below. In the interest of clarity, not all features of an actual implementation are described in this specification. In the development of any such actual embodiment, numerous implementation-specific decisions may need to be made to achieve the design-specific goals, which may vary from one implementation to another. It will be appreciated that such a development effort, while possibly complex and time-consuming, would nevertheless be a routine undertaking for persons of ordinary skill in the art having the benefit of this disclosure.

Embodiments of this disclosure present techniques to efficiently and accurately model complex subterranean fracture geometries using unstructured grids. Through non-neighboring connections (NNCs), an embedded discrete fracture modeling (EDFM) formulation is applied to data representing a subterranean region to accurately model or simulate formations with complex geometries such as fracture networks and nonplanar fractures. The EDFM formulations are combined with an element-based finite-volume method. The data representing the subterranean region to be modeled may be obtained by conventional means as known in the art, such as formation evaluation techniques, reservoir surveys, seismic exploration, etc. The subterranean region data may comprise information relating to the fractures, the reservoir, and the well(s), including number, location, orientation, length, height, aperture, permeability, reservoir size, reservoir permeability, reservoir depth, well number, well radius, well trajectory, etc.

Some embodiments utilize data representing the subterranean region produced by conventional reservoir simulators as known in the art. For example, commercial oilfield reservoir simulators such as those offered by Computer Modelling Group Ltd. and Schlumberger Technology Corporation's ECLIPSE® product can be used with embodiments of this disclosure. Other examples of conventional simulators are described in U.S. Pat. No. 5,992,519 and WO2004/049216. Other examples of these modeling techniques are proposed in WO2017/030725, U.S. Pat. Nos. 6,313,837, 7,523,024, 7,248,259, 7,478,024, 7,565,278, and 7,542,037. Conventional simulators are designed to generate models of subterranean regions, producing data sets including a matrix grid, fracture parameters, well parameters, and other parameters related to the specific production or operation of the particular field or reservoir. Embodiments of this disclosure provide a non-intrusive application of an EDFM formulation that allows for insertion of discrete fractures into a computational domain and the use of a simulator's original functionalities without requiring access to the simulator source code. The embodiments may be easily integrated into existing frameworks for conventional or unconventional reservoirs to perform various analyses as described herein.

### I. EDFM in Conventional Finite-Difference Reservoir Simulators

Embodiments of this disclosure employ an approach that creates fracture cells in contact with corresponding matrix cells to account for the mass transfer between continua. Once a fracture interacts with a matrix cell (e.g. fully or partially penetrating a matrix cell), a new additional cell is created to represent the fracture segment in the physical domain. The individual fractures are discretized into several fracture segments by the matrix cell boundaries. To differentiate the newly added cells from the original matrix cells, these additional cells are referred to herein as “fracture cells.”

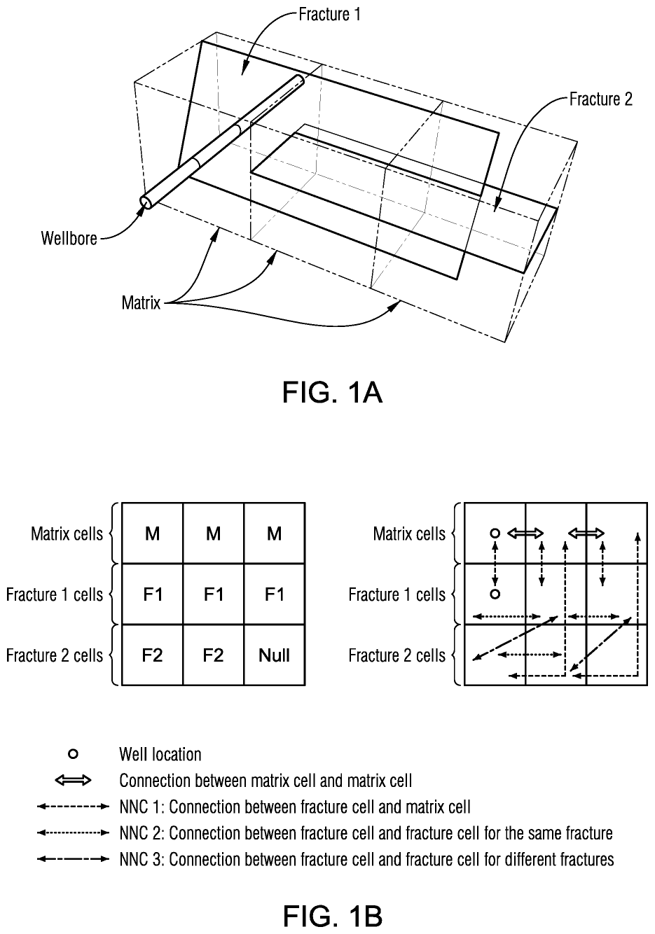

FIG. 1A depicts the procedure to add fracture cells in the EDFM using a simple case with only three matrix blocks and two fractures. FIG. 1A depicts the physical domain. FIG. 1B depicts the corresponding computational domain. In this exemplary embodiment, the physical domain includes three matrix cells, two inclined fractures and one wellbore. Before adding the two fractures, the computational domain includes three matrix cells: cell 1 (M), cell 2 (M), and cell 3 (M). After adding the fractures, the total number of cells will increase. Fracture 1 intersects three matrix cells and is discretized into three fracture segments. In the computational domain, three new extra fracture cells are added: cell 4 (F1), cell 5 (F1), and cell 6 (F1). Similarly, fracture 2 intersects two matrix cells and is discretized into two fracture segments. Two new extra fracture cells are added: cell 7 (F2) and cell 8 (F2). A Null cell is introduced to have the same number of cells in each row. The total number of cells increases from three (1×3=3) to nine (3×3=9). The depth of each fracture cell is defined as the depth of the centroid of the corresponding fracture segment. In some embodiments, physical properties (e.g., permeability, saturation, etc.) may be assigned to each fracture cell. For example, an effective porosity value may be assigned for each fracture cell to maintain the pore volume of the fracture segment:

$${φ}_{f} = \frac{{S}_{seg} {w}_{f}}{{V}_{b}} , \qquad ( 1 )$$

where ϕ_{f} is the effective porosity for a fracture cell, s_{seg} is the area of the fracture segment perpendicular to the fracture aperture, w_{f} is the fracture aperture, and v_{b} is the bulk volume of the cells assigned for the fracture segment.

Some conventional reservoir simulators generate connections between the cells. After adding the new extra fracture cells, the EDFM formulation cancels any of these simulator-generated connections. The EDFM then identifies and defines the NNCs between the added fracture cells and matrix cells. NNCs are introduced to address flow communication between cells that are physically connected but not neighboring in the computational domain. The EDFM calculates the transmissibility based on the following definitions:

a) NNC 1: connection between fracture cell and matrix cell

b) NNC 2: connection between fracture cell and fracture cell for the same fracture

c) NNC 3: connection between fracture cell and fracture cell for different fractures.

These different types of NNCs are illustrated in FIG. 1B. The cells in each NNC pair are connected by transmissibility factors. In addition to these NNCs, the connections between fractures and wells are also introduced by the EDFM. When a fracture segment intersects the wellbore trajectory (as shown in FIG. 1A), a corresponding fracture cell is defined as a wellblock by adding a well location for this cell as shown in FIG. 1B.

This general procedure may be implemented with conventional reservoir simulators or with other applications that generate similar data sets. As a non-intrusive method, the calculations of connection factors, including NNC transmissibility factors and a fracture well index, depend on the gridding, reservoir permeability, and fracture geometries. Embodiments of this disclosure apply a preprocessor to provide the geometrical calculations. Taking the reservoir and gridding information as inputs, the preprocessor performs the calculations disclosed herein and generates an output of data values corresponding to fracture locations, connectivity parameters, geometry parameters, the number of extra grids, the equivalent properties of these grids, transmissibility factors, NNC pairings, and other factors and parameters as disclosed herein. Embodiments of the preprocessor may be developed using conventional programming languages (e.g., PYTHON™, FORTRAN™, C, C++, etc.). Additional description regarding the preprocessor is provided below.

### II. Calculation of NNC Transmissibility and Fracture Well Index

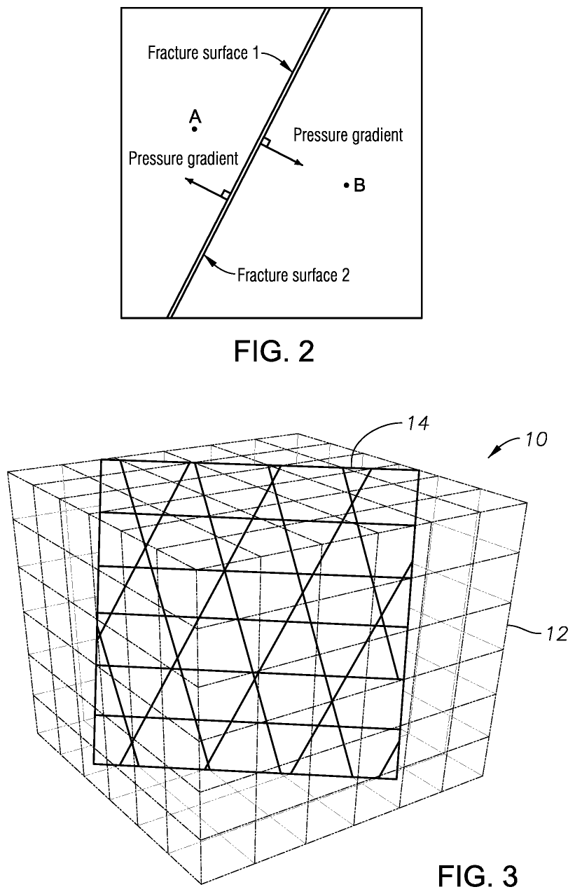

Matrix-Fracture Connection. The NNC transmissibility factor between a matrix and fracture segment depends on the matrix permeability and fracture geometry. When a fracture segment fully penetrates a matrix cell, if one assumes a uniform pressure gradient in the matrix cell and that the pressure gradient is normal to the fracture plane as shown in FIG. 2, the matrix-fracture transmissibility factor is

$${T}_{f - m} = \frac{2 {A}_{f} ( K \cdot \vec{n} ) \cdot \vec{n}}{{d}_{f - m}} , \qquad ( 2 )$$

where A_{f} is the area of the fracture segment on one side, K is the matrix permeability tensor, \vec{n} is the normal vector of the fracture plane, d_{f-m} is the average normal distance from matrix to fracture, which is calculated as

$${d}_{f - m} = \frac{{\int }_{V} {x}_{n} dV}{V} , \qquad ( 3 )$$

where V is the volume of the matrix cell, dV is the volume element of matrix, and xₙ is the distance from the volume element to the fracture plane. A more detailed derivation of Equation (2) is provided in Appendix A.

If the fracture does not fully penetrate the matrix cell, the calculation of the transmissibility factor should take into account that the pressure distribution in the matrix cell may deviate from the previous assumptions. In order to implement a non-intrusive process, one can assume that the transmissibility factor is proportional to the area of the fracture segment inside the matrix cell.

Connection between Fracture Segments in an Individual Fracture. FIG. 3 depicts a 3D reservoir model 10 using a matrix grid 12 with one inclined fracture 14. As depicted, a fracture 12 can be discretized into many small fracture segments by the boundary of the matrix cells. Each fracture segment can have a different geometric shape, including trilateral, quadrilateral, pentagons, and hexagons. Thus, the connection between these segments is a 2D unstructured grid problem. To facilitate the implementation of conventional simulators, a simplified approximation may be adopted. The transmissibility factor between a pair of neighboring segments, 1 and 2, is evaluated using a two-point flux approximation scheme as

$$\begin{matrix}{T}_{seg} = \frac{{T}_{1} {T}_{2}}{{T}_{1} + {T}_{2}} , & ( 4 a ) \\ {T}_{1} = \frac{{k}_{f} {A}_{c}}{{d}_{seg 1}} , {T}_{2} = \frac{{k}_{f} {A}_{c}}{{d}_{seg 2}} , & ( 4 b )\end{matrix}$$

where k_{f} is the fracture permeability, A_{c} is the area of the common face for these two segments, d_{seg1} and d_{seg2} are the distances from the centroids of segments 1 and 2 to the common face, respectively. This two-point flux approximation scheme may lose some accuracy for 3D cases where the fracture segments may not form orthogonal grids. When the flow in the fracture plane becomes vital for the total flow, a multi-point flux approximation may be applied. In some embodiments, the EDFM preprocessor calculates the phase independent part of the connection factors, and the phase dependent part is calculated by the simulator.

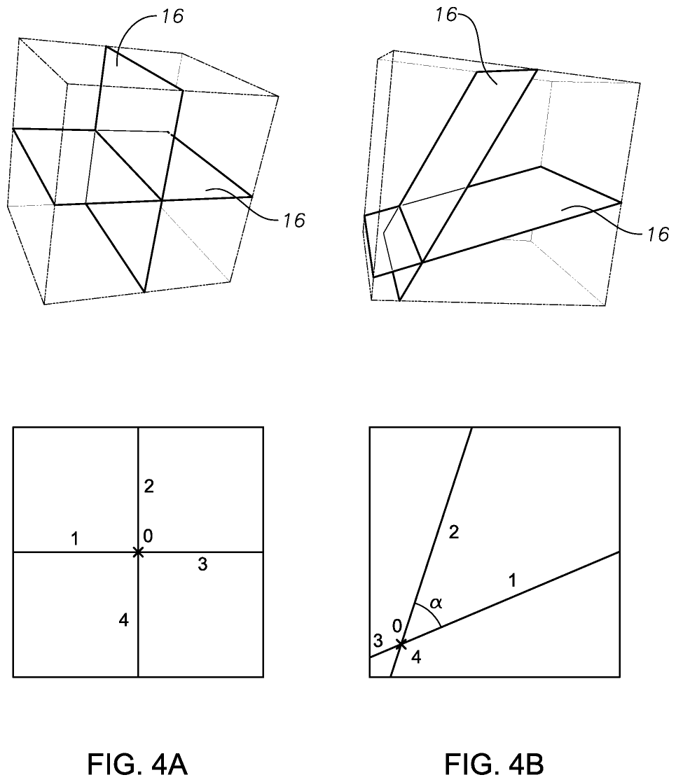

Fracture Intersection. FIG. 4A and FIG. 4B depict sample fracture 16 intersections in a 3D view (upper) and 2D view (lower). At intersections, the fractures 16 can be divided into two subsegments. In FIG. 4A, all of the subsegments have similar dimensions. In FIG. 4B, there is high contrast between areas of the subsegments. A transmissibility factor is assigned between intersecting fracture segments to approximate the mass transfer at the fracture intersection. The transmissibility factor is calculated as

$$\begin{matrix}{T}_{int} = \frac{{T}_{1} {T}_{2}}{{T}_{1} + {T}_{2}} , & ( 5 a ) \\ {T}_{1} = \frac{{k}_{f 1} {w}_{f 1} {L}_{int}}{{d}_{f 1}} , {T}_{2} = \frac{{k}_{f 2} {w}_{f 2} {L}_{int}}{{d}_{f 2}} , & ( 5 b )\end{matrix}$$

where Lᵢₙₜ is the length of the intersection line. d_{f1} and d_{f2} are the weighted average of the normal distances from the centroids of the subsegments (on both sides) to the intersection line.

In FIGS. 4A and 4B,

$$\begin{matrix}{d}_{f 1} = \frac{{\int }_{{S}_{1}} {x}_{n} {dS}_{1} + {\int }_{{S}_{3}} {x}_{n} {dS}_{3}}{{S}_{1} + {S}_{3}} & ( 6 ) \\ {d}_{f 2} = \frac{{\int }_{{S}_{2}} {x}_{n} {dS}_{2} + {\int }_{{S}_{4}} {x}_{n} {dS}_{4}}{{S}_{2} + {S}_{4}} , & ( 7 )\end{matrix}$$

where dSᵢ is the area element and Si is the area of the fracture subsegment i. xₙ is the distance from the area element to the intersection line. It is not necessary to perform integrations for the average normal distance. Since the subsegments are polygonal, geometrical processing may be used to speed up the calculation.

Well Fracture Intersection. Well-fracture intersections are modeled by assigning an effective well index for the fracture segments that intersect the well trajectory, as

$${WI}_{f} = \frac{2 π {k}_{f} {w}_{f}}{ln ( \frac{re}{rw} )} , re = 0.14 \sqrt{{L}_{s}^{2} + {H}_{s}^{2}} , \qquad ( 8 )$$

where k_{f} is the fracture permeability, w_{f} is the fracture aperture, Lₛ is the length of the fracture segment, Hₛ is the height of the fracture segment, re is the effective radius, and rw is the wellbore radius.

### III. Modeling of Complex Fracture Geometries

Nonplanar Fracture Geometry. Mathematically, the preprocessor calculates the intersection between a plane (fracture) and a cuboid (matrix cell). To account for the complexity in fracture shape, the EDFM may be extended to handle nonplanar fracture shapes by discretizing a nonplanar fracture into several interconnected planar fracture segments. The connections between these planar fracture segments may be treated as fracture intersections.

For two intersecting fracture segments, if the two subsegments have small areas (as depicted in FIG. 4B, s₃→0, s₄→0), the transmissibility factor between the fracture segments is primarily determined by subsegments with larger areas. In Equation 6, we will have

$${d}_{f 1} = \frac{{\int }_{{S}_{1}} {x}_{n} {dS}_{1}}{{S}_{1}} , {d}_{f 2} = \frac{{\int }_{{S}_{2}} {x}_{n} {dS}_{2}}{{S}_{2}} . \qquad ( 9 )$$

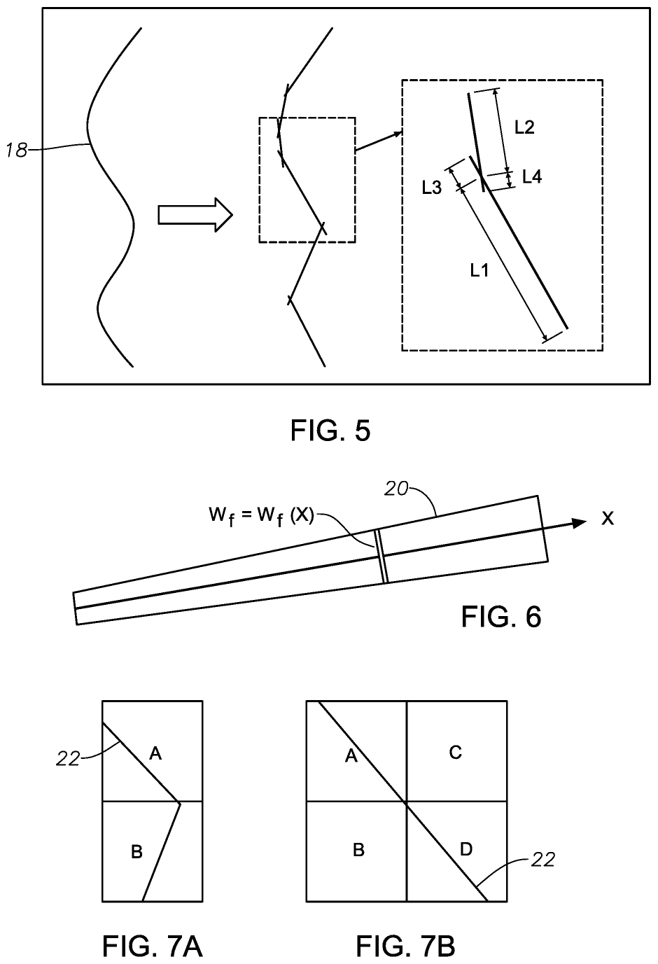

The formula for this intersecting transmissibility factor calculation (Tᵢₙₜ) has the same form as that used for two fracture segments in an individual fracture (Equation 4a), with the permeability and the aperture of the two intersecting fractures being the same. This approach is used to model nonplanar fractures. FIG. 5 depicts how EDFM embodiments handle nonplanar fractures 18. The fracture 18 is discretized into six interconnected planar fractures. For each intersection, the ratios of L1/L3 and L2/L4 should be high enough to eliminate the influence of the small subsegments. In an exemplary embodiment, the ratios are set as 100.

Fractures with Variable Aperture. A fracture with variable apertures is modeled with the EDFM by discretizing it into connecting segments and assigning each segment an “average aperture” (w̅_̅{̅f̅}̅) and “effective permeability” (k_{f,eff}). FIG. 6 shows a 2D case where a fracture 20 segment has a length of Lₛ with variable aperture and x is the distance from a cross section to one end of the fracture segment. The aperture is a function of x. The total volume of the segment is

v_{seg}=H∫₀^{L,}w_{f}(x)dx (10)

where H is the height of the fracture segment. The average aperture to calculate the volume should be

$$\overline{{w}_{f}} = {V}_{seg} \text{/} {HL}_{s} = \frac{1}{{L}_{s}} {\int }_{0}^{{L}_{s}} {w}_{f} ( x ) dx . \qquad ( 11 )$$

For transmissibility calculation, assuming the cubic law for fracture conductivity,

C_{f}(x)=k_{f}(x)w_{f}(x)=λw_{f}³(x) (12)

where λ is 1/12 for smooth fracture surfaces and λ< 1/12 for coarse fracture surfaces. For the fluid flow in fractures, based on Darcy's law,

$${Q}_{j} = {HC}_{f} ( x ) {λ}_{j} \frac{dP}{dx} , \qquad ( 13 )$$

where Qᵢ is flow rate of phase j and λⱼ is the relative mobility of phase j. For each fracture segment, assuming constant Qᵢ, the pressure drop along the fracture segment is

$$Δ p = {\int }_{0}^{{L}_{s}} \frac{{Q}_{j}}{{HC}_{f} ( x )} dx . \qquad ( 14 )$$

To keep the pressure drop constant between both ends of the segments, an effective fracture conductivity can be defined which satisfies the following equation:

$${\int }_{0}^{{L}_{s}} \frac{{Q}_{j}}{{HC}_{f} ( x )} dx = {\int }_{0}^{{L}_{s}} \frac{{Q}_{j}}{{HC}_{f}^{eff} ( x )} dx , \qquad ( 15 )$$

which gives

$${C}_{f}^{eff} = \frac{{L}_{s}}{{\int }_{0}^{{L}_{s}} \frac{dx}{{C}_{f} ( x )}} = \frac{{L}_{s}}{{\int }_{0}^{{L}_{s}} \frac{dx}{λ {w}_{f}^{3} ( x )}} . \qquad ( 16 )$$

Since the fracture conductivity is the product of fracture aperture and fracture permeability, if w̅_̅{̅f̅}̅ is used for the whole fracture segment, an effective fracture permeability k_{f,eff} is required to calculate the conductivity:

$${k}_{f , eff} = {C}_{f}^{eff} \text{/} \overline{{w}_{f}} = \frac{{L}_{s}^{2}}{( {\int }_{0}^{{L}_{s}} {w}_{f} ( x ) dx ) ( {\int }_{0}^{{L}_{s}} \frac{dx}{λ {w}_{f}^{3} ( x )} )} . \qquad ( 17 )$$

Similarly, assuming constant fracture permeability but varying aperture, the effective fracture permeability should be

$${k}_{f , eff} = \frac{{L}_{s}^{2}}{( {\int }_{0}^{{L}_{s}} {w}_{f} ( x ) dx ) ( {\int }_{0}^{{L}_{s}} \frac{dx}{{k}_{f} {w}_{f} ( x )} )} . \qquad ( 18 )$$

Special Handling of Extra Small Fracture Segments. The discretization of fractures by cell boundaries may generate some fracture segments with extremely small volumes. This happens frequently when modeling complex fracture geometries, where a large number of small fractures are used to represent the nonplanar shape and variation in aperture. These small control volumes may cause problems in preconditioning and they limit the simulation time step to an unreasonable value. Simply eliminating these segments may cause the loss of connectivity as depicted in FIGS. 7A and 7B. Lines 22 represent the fracture segments. In both FIGS. 7A and 7B, removing the fracture segment in Cell B will lead to loss of connectivity. For a fracture segment with extra small volume, if N denotes the number of NNCs related to this fracture segment, C₁, C₂, . . . C_{N} denotes the cells connected to this segment by NNC, and T₁, T₂ . . . T_{N} denotes the NNC transmissibility factor related to these connections, then the small segment can be eliminated as follows:
a) Remove the cell for this segment in the computational domain and eliminate all NNCs related to this cell.
b) Add N(N−1)/2 connections for any pair of cells in C₁, C₂, . . . C_{N}, and the transmissibility between Cᵢ and Cⱼ is

$${T}_{i , j} = \frac{{T}_{i} {T}_{j}}{{\sum }_{k = 1}^{N} {T}_{k}} . \qquad ( 19 )$$

This special case method eliminates the small control volumes while keeping the appropriate connectivity. However, for multiphase flow an approximation is provided as only the phase independent part of transmissibility is considered in the transformation. This method may also cause loss of fracture-well connection if applied for fracture segments with well intersections. Since this method ignores the volume of the small fracture segments, it is most applicable when a very high pore volume contrast (e.g. 1000) exists between fracture cells.

### IV. Element-Based Finite-Volume Approximation

The disclosed embodiments apply the EDFM formulations in unstructured grids using a control-volume finite-element numerical approximation. The computational grids used in this scheme are defined as a series of elements, and most physical properties are evaluated at the vertices of the elements in this method. An advantage of this method is that it can be easily implemented in simulators with the capability to construct arbitrary connections between cells. Since the control-volume finite-element method uses a finite-volume formulation, it is referred to herein as the element-based finite-volume method (EbFVM). The embodiments apply EDFM formulations to 2D and 3D unstructured grids (with mixed elements) using EbFVM.

Two-dimensional grids. In two-dimensional grids, linear triangular and bi-linear quadrilateral elements can be used. The porosity and permeability may be defined for each element, and other physical properties may be evaluated on vertices. Each element of the grid is divided into sub-elements, and the conservation equation is integrated for each sub-element. For this reason, the sub-elements are referred to herein as sub-control volumes (SCVs).

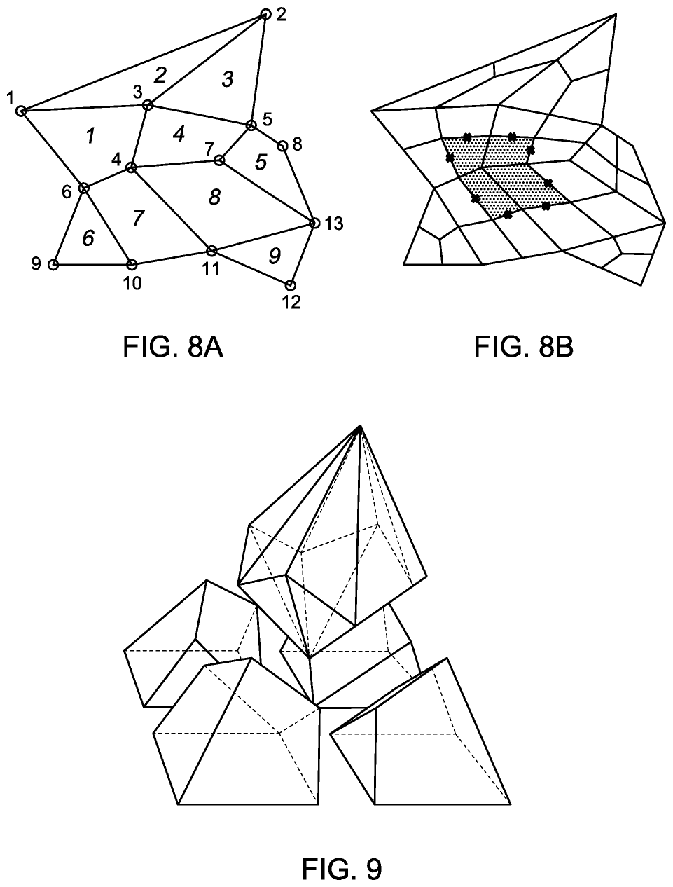

FIG. 8A depicts a two-dimensional mesh of an unstructured grid produced according to the disclosed embodiments. The mesh contains thirteen vertices and nine elements. The blue lines represent the element boundaries. In FIG. 8B, each element in the mesh is divided into several parts by connecting the centroid of the element to the middle points of the element edges. Therefore, each triangular element is divided into three parts, and each quadrilateral element is divided into four parts. Each part of the element is called an SCV. The control volume (CV) around each vertex of the grid is created through the contribution of all SCVs that share that vertex.

In FIG. 8B, the CV around vertex 4 (shown in red) is made up of SCVs from elements 1, 4, 7, and 8. The integration points for the CV are depicted as well. Using this approach, the total number of CVs is always the same as the number of vertices. Therefore, in FIG. 8B, a total number of thirteen CVs are created. The green lines represent the boundaries of the CVs. In the simulator, physical properties such as pressure, phase saturation, and the number of moles of each component may be calculated for each CV.

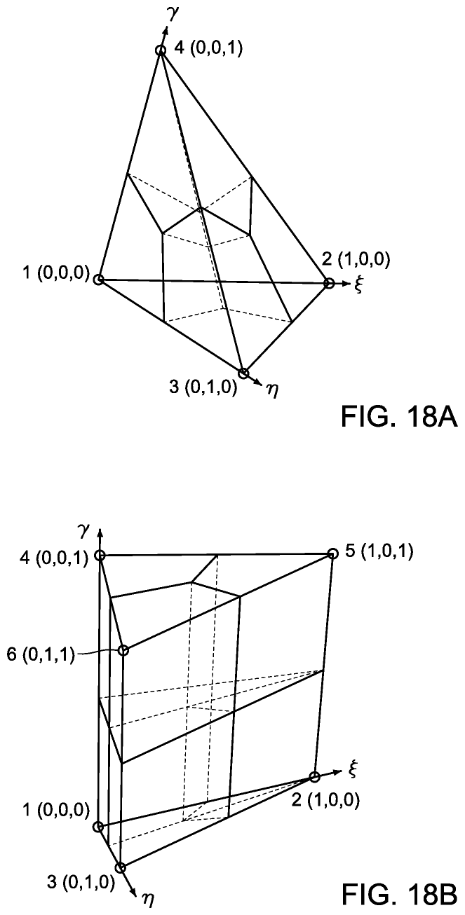

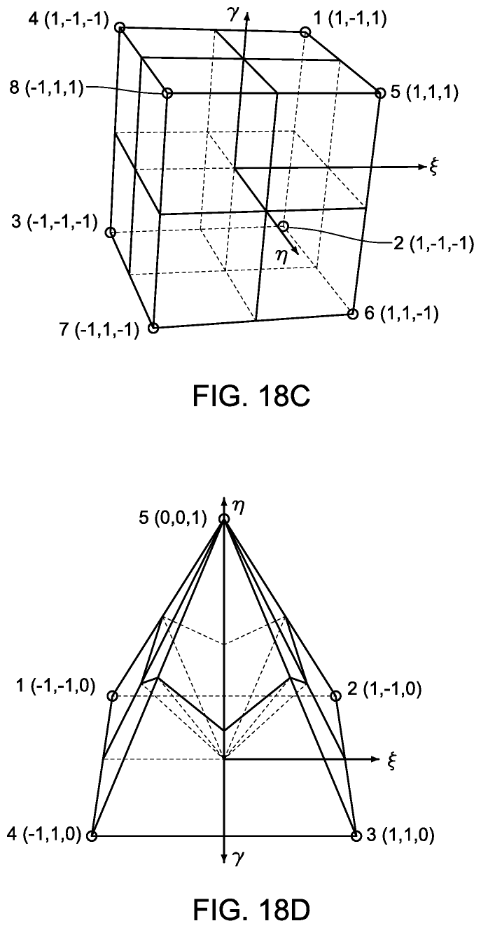

Three-dimensional grids. The basic ideas used for 3D grids are similar to those in 2D grids. However, 3D grids are typically much more complicated than 2D grids. Four types of elements can be used in 3D grids—tetrahedron, prism, hexahedron, and pyramid. Each element is discretized into several SCVs following the same process as for 2D grids. FIG. 9 depicts the splitting of a pyramid element. The splitting points are the middle points of element edges and the centroids of element faces. Splitting points for other types of elements are depicted in FIGS. 18A-18D.

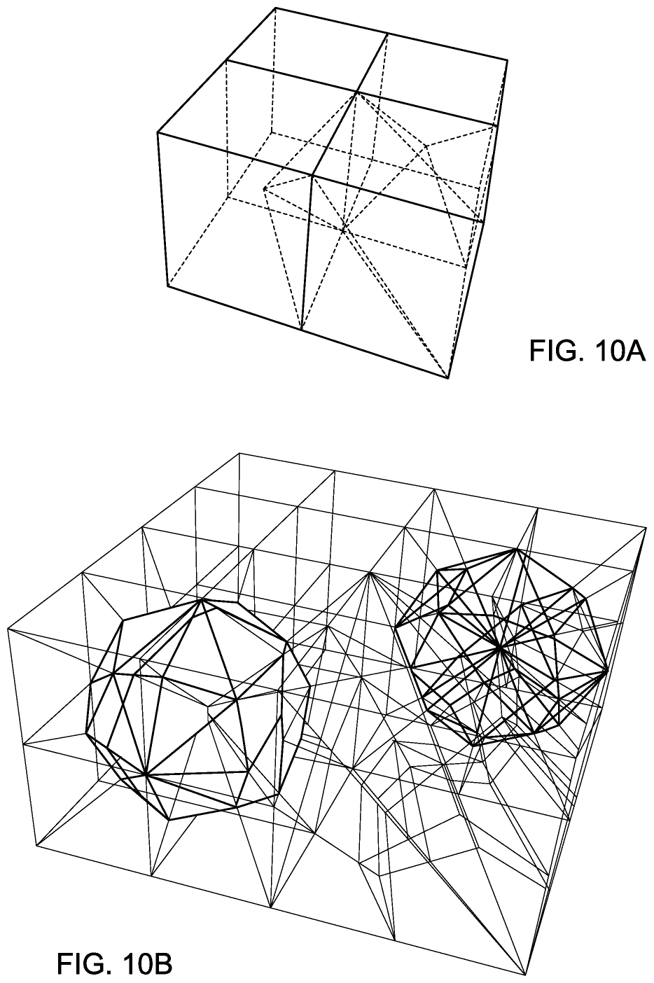

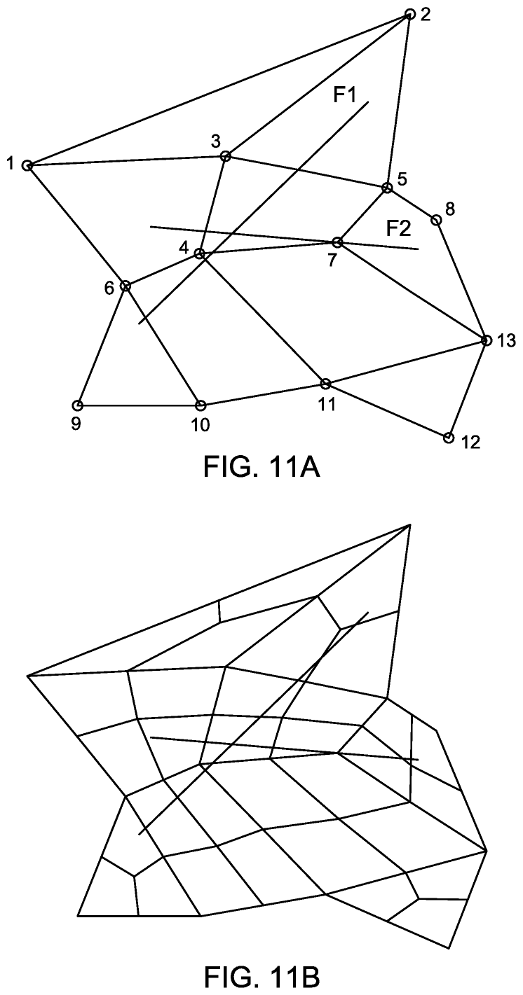

After discretization of the elements, the SCVs that share the same vertex form a CV. FIG. 10A depicts a 3D grid with three types of elements. The grid is made up of ten tetrahedron elements, one hexahedron element, and one pyramid element. These elements are split into SCVs, and the discretization is depicted in FIG. 10B. In FIG. 10B, the SCVs that belong to one CV are shown in blue. It can be seen that each CV may have a very irregular geometry.

Evaluation of flux. The reason to subdivide the elements into SCVs in the EbFVM is to make it convenient to evaluate the flux between blocks. As previously mentioned, in the EbFVM, physical properties such as fluid pressure are evaluated on vertices (CVs). The coordinates and physical properties inside an element can be approximated using the coordinates and properties at the vertices. For the two-dimensional elements,

$$x ( ξ , η ) = {\sum }_{i = 1}^{{N}_{v}} {N}_{i} {x}_{i} ; \\ y ( ξ , η ) = {\sum }_{i = 1}^{{N}_{v}} {N}_{i} {y}_{i} ; \\ Φ ( ξ , η ) = {\sum }_{i = 1}^{{N}_{v}} {N}_{i} {Φ}_{i} . \qquad ( 20 )$$

For the three-dimensional elements,

$$x ( ξ , η , γ ) = {\sum }_{i = 1}^{{N}_{v}} {N}_{i} {x}_{i} ; \\ y ( ξ , η , γ ) = {\sum }_{i = 1}^{{N}_{v}} {N}_{i} {y}_{i} ; \\ z ( ξ , η , γ ) = {\sum }_{i = 1}^{{N}_{v}} {N}_{i} {z}_{i} ; \\ Φ ( ξ , η , γ ) = {\sum }_{i = 1}^{{N}_{v}} {N}_{i} {Φ}_{i} . \qquad ( 21 )$$

In Equations (20) and (21), x, y, and Z are the Cartesian coordinates of a point in the element, ξ, η, and γ are local coordinates in the computational plane, Nᵥ is the number of vertices of the element, Nᵢ is the shape function, xᵢ, yᵢ, and zᵢ are the Cartesian coordinates of vertex i, and Φᵢ is the physical property at vertex i. The shape functions for 2D and 3D elements in the computational plane are presented in Appendix B.

Using Equations (20) and (21), the gradient of physical properties can be evaluated as

$$\frac{\partial Φ}{\partial x} = {\sum }_{i = 1}^{{N}_{v}} \frac{\partial {N}_{i}}{\partial x} {Φ}_{i} ; \\ \frac{\partial Φ}{\partial y} = {\sum }_{i = 1}^{{N}_{v}} \frac{\partial {N}_{i}}{\partial y} {Φ}_{i} ; \\ \frac{\partial Φ}{\partial z} = {\sum }_{i = 1}^{{N}_{v}} \frac{\partial {N}_{i}}{\partial z} {Φ}_{i} ( for three \text{-} dimensional elements ) . \qquad ( 22 )$$

For two-dimensional grids,

$$\frac{\partial {N}_{i}}{\partial x} and \frac{\partial {N}_{i}}{\partial y}$$

can be obtained by solving the following linear system:

$$\frac{\partial {N}_{i}}{\partial ξ} = \frac{\partial {N}_{i}}{\partial x} \frac{\partial x}{\partial ξ} + \frac{\partial {N}_{i}}{\partial y} \frac{\partial y}{\partial ξ} ; \\ \frac{\partial {N}_{i}}{\partial η} = \frac{\partial {N}_{i}}{\partial x} \frac{\partial x}{\partial η} + \frac{\partial {N}_{i}}{\partial y} \frac{\partial y}{\partial η} . \qquad ( 23 )$$

For three-dimensional grids, the following system should be solved to obtain

$$\frac{\partial {N}_{i}}{\partial x} , \frac{\partial {N}_{i}}{\partial y} , , and \frac{\partial {N}_{i}}{\partial z} \text{:}$$

$$\frac{\partial {N}_{i}}{\partial ξ} = \frac{\partial {N}_{i}}{\partial x} \frac{\partial x}{\partial ξ} + \frac{\partial {N}_{i}}{\partial y} \frac{\partial y}{\partial ξ} + \frac{\partial {N}_{i}}{\partial z} \frac{\partial z}{\partial ξ} ; \\ \frac{\partial {N}_{i}}{\partial η} = \frac{\partial {N}_{i}}{\partial x} \frac{\partial x}{\partial η} + \frac{\partial {N}_{i}}{\partial y} \frac{\partial y}{\partial η} + \frac{\partial {N}_{i}}{\partial z} \frac{\partial z}{\partial η} ; \\ \frac{\partial {N}_{i}}{\partial γ} = \frac{\partial {N}_{i}}{\partial x} \frac{\partial x}{\partial γ} + \frac{\partial {N}_{i}}{\partial y} \frac{\partial y}{\partial γ} + \frac{\partial {N}_{i}}{\partial z} \frac{\partial z}{\partial γ} . \qquad ( 24 )$$

With the gradient of physical properties (e.g. flow potential gradient), the total molar flow rate of component k across the boundaries of an SCV through advection can be evaluated through an integration:

$${F}_{k} = {\sum }_{l = 1}^{{N}_{ip}} {\sum }_{j = 1}^{{n}_{p}} {x}_{kj} {ξ}_{j} \frac{{k}_{rj}}{{μ}_{j}} \cdot {Φ}_{jl} , \qquad ( 25 )$$

where Nᵢₚ is the number of integration points, nₚ is the number of phases, xₖⱼ is the mole fraction of component k in phase j, ξⱼ is the molar density of phase j, kᵣⱼ is the relative permeability of phase j, μⱼ is the viscosity of phase j, [symbol] is the permeability tensor, [symbol] is the flow potential gradient at the l^{th} integration point evaluated by Equation (22), and [symbol] is the area of the interface. [symbol] Each integration point is the center of the interface between two SCVs. The integration is performed on every interface between two SCVs within the same element. The integration points in 2D elements are shown in Appendix B. For 3D elements, the interfaces can also be easily found in FIG. 9. Since the integration is calculated within the element, the same permeability value can be used on both sides of the interface, and no interpolation is required for the evaluation of flux. The fluid properties in Equation (25) are evaluated by an upstream scheme depending on the sign of [symbol] .

Ignoring the physical dispersion term, the material balance equation used in the simulator is

$$\frac{\partial {N}_{k}}{\partial t} = {F}_{k} + {q}_{k} , k = 1 , … , {n}_{c} + 1 , \qquad ( 26 )$$

where Nₖ is the number of moles of component k, qₖ is the injection/production molar rate of component k from wells, and n is the number of hydrocarbon components. Component n_{c}+1 denotes the water component. In the EbFVM, Equation (26) is integrated for every SCV of every element. After that, an assembly process is performed using all SCVs that share the same vertex (within the same CV). Overall, the calculations are performed in each element, and the assembly process is performed to obtain the material balance equation of each CV.

EDFM in unstructured grids using the EbFVM. The basic idea to apply the EDFM to unstructured grids is similar to that in Cartesian and corner-point grids. Additional CVs are created in the computational domain to represent the fracture segments, and NNCs are constructed to represent different types of flows related to fractures and matrix gridblocks crossed by fractures. The matrix permeability is defined on elements. However, the physical properties to evaluate in the simulation (pressure, saturation, etc.) are defined on CVs. The geometrical calculations of matrix-fracture intersections (Type I NNCs) are performed on SCVs.

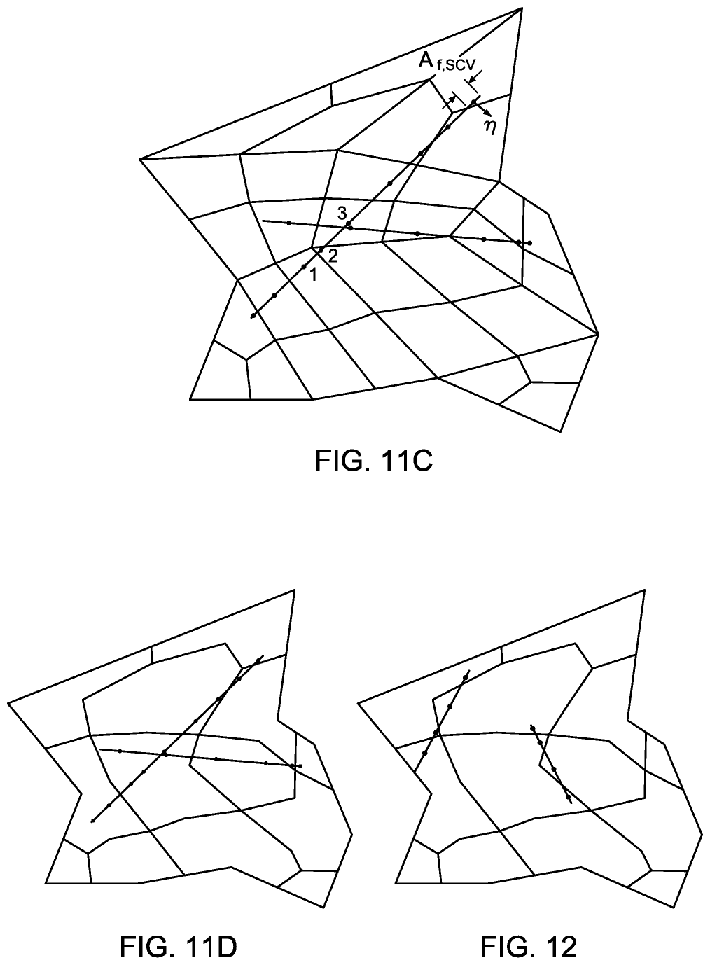

FIG. 11A depicts a procedure to obtain fracture segments and calculate matrix-fracture connections in accordance with embodiments of this disclosure. Initially, the fractures are placed inside the grid made up with elements. The vertices are labeled 1-13. The red lines represent fractures (“F1” and “F2”), the blue lines represent the element boundaries. The elements are then divided into SCVs for the geometrical calculation (FIG. 11B). The green lines represent the boundaries of control volumes. After that, intersections between the fracture polygons and SCVs are calculated. During the calculation, each SCV is treated as a general polyhedron. After the calculation, the fractures are discretized into a series of fracture segments (the center of each fracture segment is shown), and each fracture segment is contained in an SCV, as depicted in FIG. 11C. The transmissibility factor between an SCV and a fracture segment inside it can be evaluated as

$${T}_{f - SCV} = \frac{2 {A}_{f , SCV} {n}^{r} \cdot ( {SCV}_{} \cdot {n}^{r} )}{{d}_{f - CV}} , \qquad ( 27 )$$

where A_{f,SCV} is the area of the fracture segment in the SCV, [symbol] is the unit normal vector of the fracture plane, [symbol] _{SCV} is the permeability tensor of the SCV, which is the same as the permeability tensor of the corresponding element, and d_{f-CV} is the average normal distance from the fracture segment to the CV that the SCV belongs to. For illustration purposes, in FIG. 11C, A_{f,SCV} and [symbol] for a fracture segment is shown. The derivation of Equation (27) assumes a linear pressure distribution in the CV, which is suitable for cases where all SCVs in the CV have the same porosity and permeability. For reservoirs with heterogeneous porosity and permeability fields, Equation (27) is a rough approximation.

In the last step, the fracture segments belonging to the same fracture and contained in the same CV are merged if they share a common edge. FIG. 11D depicts the fracture segments merged within the same CV. The center of each fracture segment after the merging process is shown. The connectivity factors between fractures and CVs may then be calculated. As an example, in FIG. 11C, the three fracture segments (“1,” “2,” and “3”) belonging to the fracture “F1” in the CV around vertex 4 are merged into one fracture segment. The purpose of merging the fracture segments is to reduce the number of fracture segments (the same as the number of CVs) for each fracture. After the merging process, the transmissibility factor between a CV and the fracture segment inside it is calculated as

$${T}_{f - CV} = {\sum }_{i = 1}^{{N}_{merge}} {T}_{f - SCV , i} , \qquad ( 28 )$$

where N_{merge} is the number of initial fracture segments (in FIG. 11C) that the fracture segment is merged from.

For two-dimensional grids, some CVs have a concave geometry, and thus not all fracture segments in a CV may be merged into one. It is possible for a fracture to have multiple fracture segments in a single CV. FIG. 12 depicts an example of this situation, a 2D example where the fracture segments in a CV are merged into multiple fracture segments. The green lines are the boundaries of CVs.

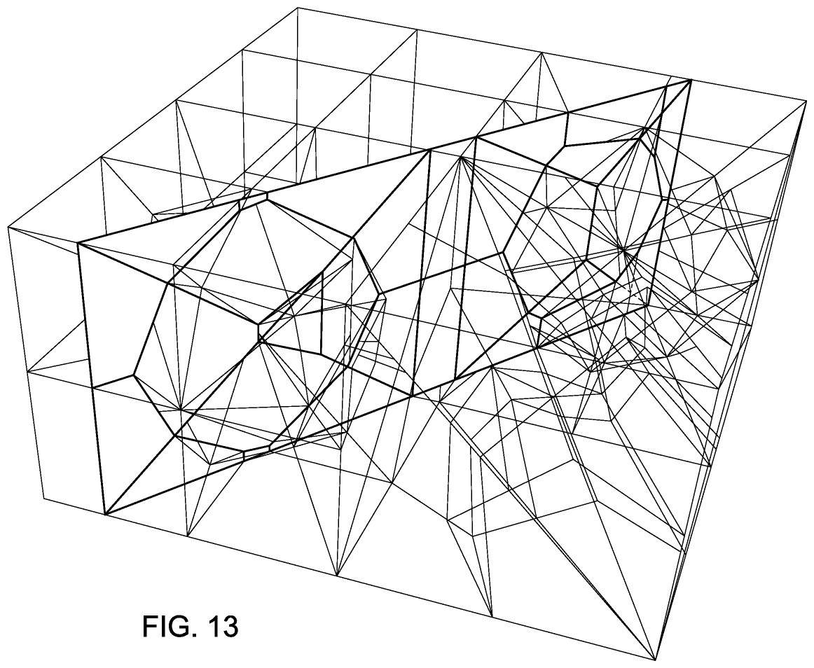

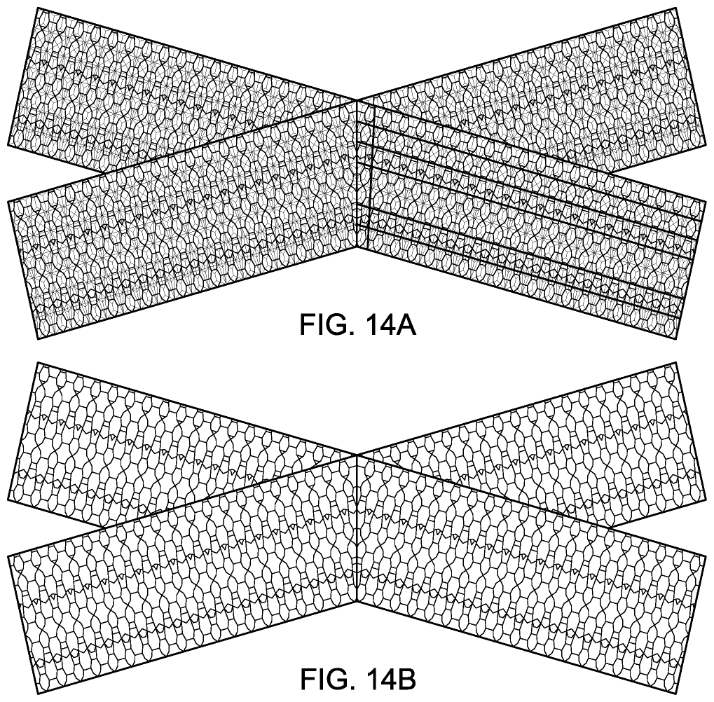

For 3D grids, it is not always the case that all fracture segments in a CV can be merged into one fracture segment. In addition, the merging of fracture segments is more complicated compared to the 2D cases. FIG. 13 depicts an example where a fracture is placed in the grid in FIG. 10B. The fracture segments contained in the same CV are shown in the same color, and these fracture segments are to be merged. FIG. 14A and FIG. 14B depict a larger example for the merging of fracture segments, where two fractures are placed in a grid made up of pyramid elements. FIG. 14A depicts the fracture segments before the merging process. FIG. 14B depicts the fracture segments after the merging process. In FIG. 14B, the number of fracture segments decreases from 12,348 to 1,823 through the merging process. Since each CV contains more SCVs in 3D grids compared to 2D grids, the step of fracture segment merging has more benefits in reducing the number of fracture CVs in 3D grids. The transmissibility factor calculations for Type II NNCS, Type III NNCs, and well-fracture intersections in the EDFM are very similar to those in Cartesian grids.

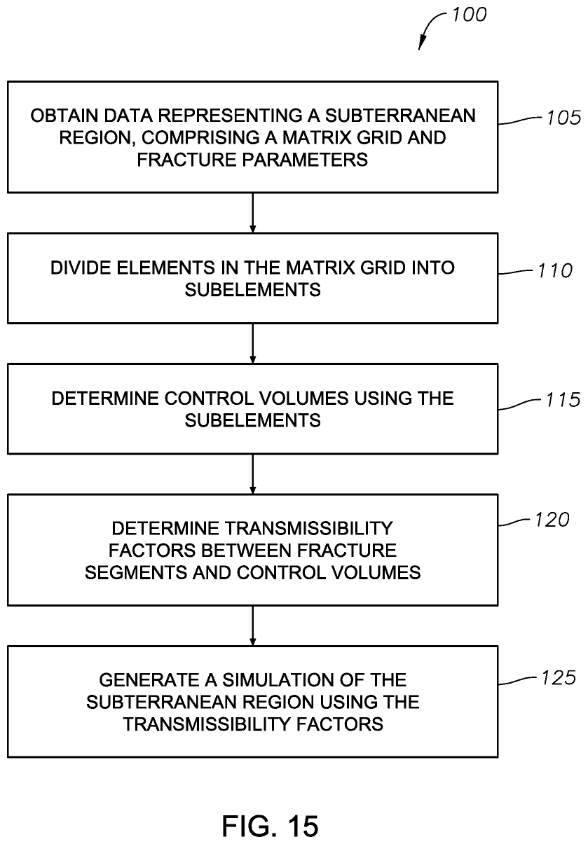

In accordance with some embodiments, FIG. 15 is a flow chart illustrating a process 100 for simulating a subterranean region having fracture geometries. At step 105, data representing a subterranean region is obtained, the data comprising a matrix grid and fracture parameters. As disclosed herein, the data set may be obtained as the output generated by a conventional commercial simulator or attained by other means as known in the art, such as formation evaluation logging techniques, seismic surveys, cross-well surveys, etc. At step 110, elements in the matrix grid are divided into sub-elements. At step 115, control volumes are determined using the sub-elements. At step 120, transmissibility factors are determined between fracture segments and the control volumes. At step 125, a simulation of the subterranean region is generated using the transmissibility factors. This process is performed in accordance with the disclosed techniques.

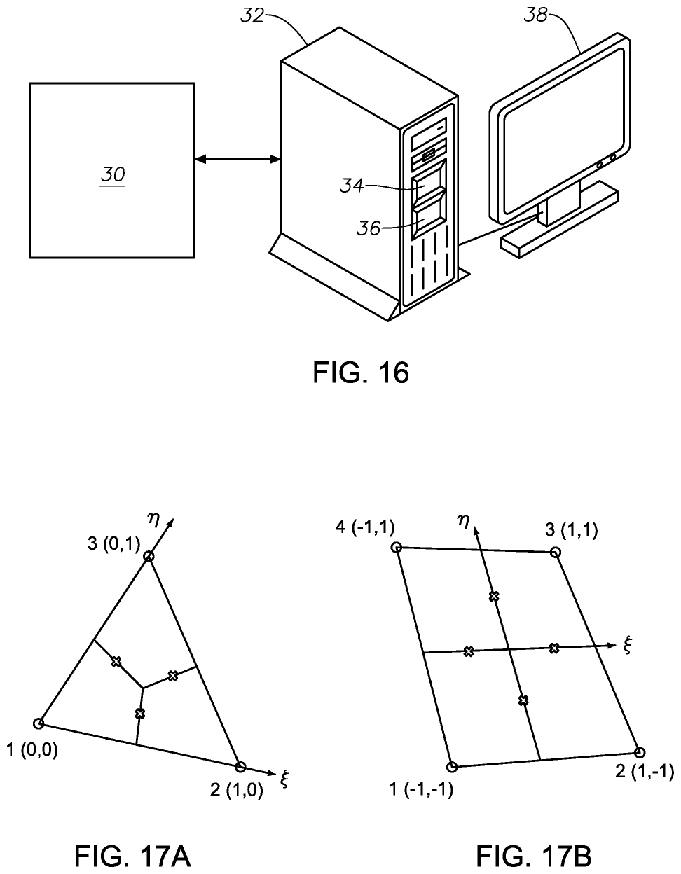

As previously described, a preprocessor algorithm is used to perform the disclosed calculations. FIG. 16 depicts a system for implementation of embodiments of this disclosure. A simulator module 30 is linked to a computer 32 configured with a microprocessor 34 and memory 36 that can be programmed to perform the steps and processes disclosed herein. The output values calculated by the computer 32 are used as data input (commonly referred to as “keywords”) to the simulator module 30 for generation of the desired simulation. In this manner, the disclosed EDFM and EbFVM formulations are applied in a non-intrusive way in conjunction with conventional simulators. The formulations keeps the grids of conventional simulators and models the fractures implicitly through different types of connection factors as described herein, without requiring access to or use of the simulator's source code. Alternatively, some embodiments may be implemented as a unitary application (i.e. wherein one module performs both the simulator and preprocessor functions). A display 38 is linked to the computer 32 to provide a visual output of the simulation results. It will be appreciated by those skilled in the art that conventional software and computer systems may be used to implement the embodiments. It will also be appreciated that programming of the computer 32 and microprocessor 34 can be implemented via any suitable computer language coding in accordance with the techniques disclosed herein. In some embodiments, the simulator module 30 may be remotely located (e.g. at a field site) and linked to the computer 32 via a communication network.

Advantages provided by the embodiments of this disclosure include the ability to accurately simulate subsurface characteristics and provide useful data (e.g., transient flow around fractures, fluid flow rates, fluid distribution, fluid saturation, pressure behavior, geothermal activity, well performance, formation distributions, history matching, production forecasting, saturation levels, sensitivity analysis, temperature gradients, etc.), particularly for multi-scale complex fracture geometries. The embodiments are ideal for use in conjunction with commercial simulators in a non-intrusive manner, overcoming key limitations of low computational efficiency and complex gridding issues experienced with conventional methods. 2D or 3D multi-scale complex fractures can be directly embedded into unstructured matrix grids.

Embodiments of this disclosure can handle fractures with any complex boundaries and surfaces with varying roughness. It is common for fractures to have irregular shapes and varying properties (e.g. varying aperture, permeability) along the fracture plane. In such cases, the fracture shape can be represented using a polygon or polygon combinations to define the surface contours and performing the geometrical calculation between the fracture and the matrix block. The polygon(s) representing the fracture shape can be convex or concave. Embodiments can handle different types of grids, including Cartesian grids and complex corner-point grids.

Embodiments of this disclosure apply the EDFM approach in 2D and 3D unstructured grids using the EbFVM, entailing fracture discretization and evaluation of the transmissibility factors between fractures and the matrix. In 2D grids, triangular and quadrilateral elements can be used; in 3D grids, four types of elements can be used, including tetrahedron, prism, hexahedron, and pyramid. Embodiments also handle mixed elements in a single grid. Recovery processes in fractured reservoirs with complex reservoir geometries were simulated. The use of unstructured grids makes it convenient to represent the reservoir geometries, and complicated gridding around fractures is avoided, with minimum adjustment required on the original grid. The embodiments can also handle single-phase, multiple-phase, isothermal and non-isothermal processes, single well, multiple wells, single porosity models, dual porosity models, and dual permeability models. Other advantages provided by the disclosed embodiments include the ability to: transfer the fracture geometry generated from microseismic data interpretation to commercial numerical reservoir simulators for production simulation; transfer the fracture geometry generated from fracture modeling and characterization software to commercial numerical reservoir simulators for production simulation; and handle pressure-dependent matrix permeability and pressure-dependent fracture permeability.

In light of the principles and example embodiments described and illustrated herein, it will be recognized that the example embodiments can be modified in arrangement and detail without departing from such principles. Also, the foregoing discussion has focused on particular embodiments, but other configurations are also contemplated. In particular, even though expressions such as in “an embodiment,” or the like are used herein, these phrases are meant to generally reference embodiment possibilities, and are not intended to limit the invention to particular embodiment configurations. As used herein, these terms may reference the same or different embodiments that are combinable into other embodiments. As a rule, any embodiment referenced herein is freely combinable with any one or more of the other embodiments referenced herein, and any number of features of different embodiments are combinable with one another, unless indicated otherwise.

Similarly, although example processes have been described with regard to particular operations performed in a particular sequence, numerous modifications could be applied to those processes to derive numerous alternative embodiments of the present invention. For example, alternative embodiments may include processes that use fewer than all of the disclosed operations, processes that use additional operations, and processes in which the individual operations disclosed herein are combined, subdivided, rearranged, or otherwise altered. This disclosure describes one or more embodiments wherein various operations are performed by certain systems, applications, modules, components, etc. In alternative embodiments, however, those operations could be performed by different components. Also, items such as applications, modules, components, etc., may be implemented as software constructs stored in a machine accessible storage medium, such as an optical disk, a hard disk drive, etc., and those constructs may take the form of applications, programs, subroutines, instructions, objects, methods, classes, or any other suitable form of control logic; such items may also be implemented as firmware or hardware, or as any combination of software, firmware and hardware, or any combination of any two of software, firmware and hardware. It will also be appreciated by those skilled in the art that embodiments may be implemented using conventional memory in applied computing systems (e.g., local memory, virtual memory, and/or cloud-based memory). The term “processor” may refer to one or more processors.

This disclosure may include descriptions of various benefits and advantages that may be provided by various embodiments. One, some, all, or different benefits or advantages may be provided by different embodiments. In view of the wide variety of useful permutations that may be readily derived from the example embodiments described herein, this detailed description is intended to be illustrative only, and should not be taken as limiting the scope of the invention. What is claimed as the invention, therefore, are all implementations that come within the scope of the following claims, and all equivalents to such implementations.

Nomenclature
A=area, ft
B=formation volume factor
C=compressibility, psi⁻¹
C_{f}=fracture conductivity, md-ft
d=average distance, ft
dS=area element, ft²
dV=volume element, ft³
H=fracture height, ft
Hₛ=height of fracture segment, ft
K=reservoir permeability, md
k_{f}=fracture permeability, md
K=matrix permeability tensor, md
K_{α}=differential equilibrium portioning coefficient of gas at a constant temperature
L=fracture length, ft
Lᵢₙₜ=length of fracture intersection line, ft
Lₛ=length of fracture segment, ft
\vec{n}=normal vector
N=number of nnc
P=pressure, psi
Q=volume flow rate, ft³/day
Re=effective radius, ft
Rw=wellbore radius, ft
Rₛ=solution gas-oil ratio, scf/STB
S=fracture segment area, ft²
T=transmissibility, md-ft or temperature, OF
V=volume, ft³
V_{b}=bulk volume, ft³
Vₘ=langmuir isotherm constant, scf/ton
w_{f}=fracture aperture, ft
w̅_̅{̅f̅}̅=average fracture aperture, ft
WI=well index, md-ft
X=distance, ft
x_{f}=fracture half length, ft
Δp=pressure drop, psi
λ=phase mobility, cp⁻¹
μ=viscosity, cp
ρ=density, g/cm³
ϕ_{f}=fracture effective porosity

Subscripts and Superscripts
A=adsorbed
B=bulk
C=common face
Eff=effective
F=fracture
G=gas
J=phase
L=Langmuir
M=matrix
O=oil
Seg=fracture segment
ST=stock tank

Acronyms
EbFVM=Element-Based Finite-Volume Method
EDFM=Embedded Discrete Fracture Model
LGR=Local Grid Refinement
NNC=Non-Neighboring Connection
2D=Two-dimension(al)/3D=Three-dimension(al)

### APPENDIX A

Derivation of Matrix-Fracture Transmissibility Factor

As shown in FIG. 2, the matrix cell is divided into 2 parts: A and B. We denote the volume of part A and part B as v_{A} and v_{B}, respectively. The average pressure in the total matrix cell is

pₘ=(V_{A}p_{A}+V_{B}p_{B})/(V_{A}+V_{B}) (A1)

where p_{A} and p_{B} are the average pressure in part A and B, respectively. We assume the same pressure gradients in A and B as shown by the red arrows. Let d_{A} and d_{B} be the average normal distances from part A and part B to the fracture plane. The flow rate of phase j from the fracture surface 1 to part A is

Q_{f-A}=T_{f-A}λⱼ(p_{f}−p_{A}) (A2)

where p_{f} is the average pressure in the fracture segment, T_{f-A} is the phase independent part of transmissibility between fracture and part A, and λⱼ is the relative mobility of phase j. T_{f-A} can be calculated by

T_{f-A}=A_{f}(K−\vec{n})−\vec{n}/d_{f-A} (A3)

where A_{f} is the area of the fracture segment on one side, K is the matrix permeability tensor, ii is the normal vector of the fracture plane, d_{f-A} is the average normal distance from part A to fracture, which can be calculated by

$${d}_{f - A} = \frac{{\int }_{{V}_{A}} {x}_{n} {dV}_{A}}{{V}_{A}} , \qquad ( A4 )$$

(p_{f}−p_{A})n̅/d_{f-A} is the pressure gradient. In the case of anisotropic matrix permeability, the flow direction may be different from the direction of pressure gradient. Therefore, the second n̅ in the equation projects the flow velocity onto the normal direction of the fracture plane. Similarly, the flow rate of phase j from the fracture surface 2 to part B is

Q_{f-B}=T_{f-B}λ(p_{f}−p_{B}) (A5)

T_{f-B}=A_{f}(K·\vec{n})·\vec{n}/d_{f-B} (A6)

and

$${d}_{f - B} = \frac{{\int }_{{V}_{B}} {x}_{n} {dV}_{B}}{{V}_{B}} . \qquad ( A7 )$$

The total flow from fracture to matrix is

Q_{f-m}=Q_{f-A}+Q_{f-B} (A8)

By the definition of T_{f-m},

Q_{f-m}=T_{f-m}λⱼ(p_{f}−pₘ) (A9)

Assuming the same magnitude of pressure gradients on both sides of the fracture, we have

$$\frac{{p}_{f} - {p}_{A}}{{p}_{f} - {p}_{B}} = \frac{{d}_{f - A}}{{d}_{f - B}} . \qquad ( A10 )$$

Combining all these equations, we can obtain

$${T}_{f - m} = \frac{2 {A}_{f} ( K \cdot \vec{n} ) \cdot \vec{n}}{( {V}_{A} {d}_{f - A} + {V}_{B} {d}_{f - B} ) \text{/} ( {V}_{A} + {V}_{B} )} . \qquad ( A11 )$$

### APPENDIX B

### Shape Functions for Two-Dimensional and Three-Dimensional Elements

The shape function Nᵢ is defined for each type of element. In two-dimensional grids, triangular and quadrilateral elements are used. FIG. 17A and FIG. 17B respectively show the definition of (ξ, η) local coordinates in triangular and quadrilateral elements. For each vertex, the index and the (ξ, η) coordinates are shown. The integration points in the elements are also shown. The shape functions for a triangular element are

N₁(ξ,η)=1−ξ−η;

N₂(ξ,η)=ξ;

N₃(ξ,η)=η (B1)

The shape functions for a quadrilateral element are

N₁(ξ,η)=¼(1−ξ)(1−η);

N₂(ξ,η)=¼(1+ξ)(1−η);

N₃(ξ,η)=¼(1+ξ)(1+η);

N₄(ξ,η)=¼¼(1−ξ)(1+η) (B2)

In three-dimensional grids, four types of elements can be used: tetrahedron, prism, hexahedron, and pyramid. The definition of (ξ, η) local coordinates in 3D elements is presented in FIGS. 18A-18D. For each vertex, the index and the (ξ, η, γ) coordinates are shown. The shape functions for a tetrahedron element (FIG. 18A) are

N₁(ξ,η,γ)=1−ξ−η−γ;

N₂(ξ,η,γ)=ξ;

N₃(ξ,η,γ)=η

N₄(ξ,η,γ)=γ (B3)

The shape functions for a prism element (FIG. 18B) are

N₁(ξ,η,γ)=(1−ξ−η)(1−γ);

N₂(ξ,η,γ)=ξ(1−γ);

N₃(ξ,η,γ)=η(1−γ);

N₄(ξ,η,γ)=γ(1−ξ−η);

N₅(ξ,η,γ)=ξγ;

N₆(ξ,η,γ)=ηγ (B4)

The shape functions for a hexahedron element (FIG. 18C) are

N₁(ξ,η,γ)=⅛(1+ξ)(1−η)(1+γ);

N₂(ξ,η,γ)=⅛(1+ξ)(1−η)(1−γ);

N₃(ξ,η,γ)=⅛(1+ξ)(1−η)(1−γ);

N₄(ξ,η,γ)=⅛(1+ξ)(1−η)(1+γ);

N₅(ξ,η,γ)=⅛(1+ξ)(1+η)(1+γ);

N₆(ξ,η,γ)=⅛(1+ξ)(1+η)(1−γ);

N₇(ξ,η,γ)=⅛(1+ξ)(1+η)(1−γ);

N₈(ξ,η,γ)=⅛(1+ξ)(1+η)(1+γ);

The shape functions for a pyramid element (FIG. 18D) are

N₁(ξ,η,γ)=¼[(1−ξ)(1−η)−γ+ξηγ/(1−γ)];

N₂(ξ,η,γ)=¼[(1−ξ)(1−η)−γ+ξηγ/(1−γ)];

N₃(ξ,η,γ)=¼[(1−ξ)(1−η)−γ+ξηγ/(1−γ)];

N₄(ξ,η,γ)=¼[(1−ξ)(1−η)−γ+ξηγ/(1−γ)];

N₅(ξ,η,γ)=γ (B6)

What is claimed is:

1. A method for simulating a subterranean region having fracture geometries, comprising:
obtaining data representing a subterranean region, the data comprising a matrix grid and fracture parameters;
dividing elements in the matrix grid into sub-elements;
determining control volumes using the sub-elements;
determining transmissibility factors between fracture segments and the control volumes; and
generating a simulation of the subterranean region using the transmissibility factors.

2. The method of claim 1, wherein dividing elements in the matrix grid into sub-elements comprises dividing each element into several parts by connecting a centroid of the element to middle points of element edges.

3. The method of claim 2, wherein determining control volumes comprises identifying sub-elements that share a vertex to form a control volume.

4. The method of claim 1, further comprising determining physical subterranean parameters associated with the control volumes.

5. The method of claim 1, wherein determining transmissibility factors comprises determining transmissibility factors between sub-elements and fracture segments contained within the sub-elements.

6. The method of claim 1, wherein determining transmissibility factors comprises merging fracture segments of the same fracture inside a control volume.

7. The method of claim 6, wherein determining transmissibility factors comprises determining a transmissibility factor between a control volume and a fracture segment inside the volume.

8. The method of claim 1, wherein the dividing elements in the matrix grid into sub-elements, determining control volumes using the sub-elements, and determining transmissibility factors between fracture segments and the control volumes is performed via a preprocessor configured to generate corresponding output values.

9. The method of claim 8, wherein the output values generated by the preprocessor are input into a simulator for generation of the simulation of the subterranean region.

10. The method of claim 1, wherein the matrix grid data represents an unstructured grid.

11. A system for simulating a subterranean region having fracture geometries, comprising:
at least one processor;
a memory linked to the processor, the memory having instructions stored therein, which when executed cause the processor to perform functions including to:
input data representing a subterranean region, the data comprising a matrix grid and fracture parameters;
divide elements in the matrix grid into sub-elements;
determine control volumes using the sub-elements;
determine transmissibility factors between fracture segments and the control volumes; and
produce output values corresponding to the determined transmissibility factors for generation of a simulation of the subterranean region.

12. The system of claim 11, wherein the function to divide matrix grid elements into sub-elements comprises division of each element into several parts by connecting a centroid of the element to middle points of element edges.

13. The system of claim 12, wherein the function to determine control volumes comprises identification of sub-elements that share a vertex to form a control volume.

14. The system of claim 11, wherein the functions performed by the processor further include functions to determine physical subterranean parameters associated with the control volumes.

15. The system of claim 11, wherein the function to determine transmissibility factors comprises determination of transmissibility factors between sub-elements and fracture segments contained within the sub-elements.

16. The system of claim 11, wherein the function to determine transmissibility factors comprises merger of fracture segments of the same fracture inside a control volume.

17. The system of claim 16, wherein the function to determine transmissibility factors comprises determination of a transmissibility factor between a control volume and a fracture segment inside the volume.

18. The system of claim 11, wherein the functions performed by the processor further include functions to input the produced output values into a simulator for generation of the subterranean region simulation.

19. The system of claim 11, wherein the matrix grid data represents an unstructured grid.

20. A computer-readable medium, embodying instructions which when executed by a computer cause the computer to perform a plurality of functions, including functions to:
input data representing a subterranean region, the data comprising a matrix grid and fracture parameters;
divide elements in the matrix grid into sub-elements;
determine control volumes using the sub-elements;
determine transmissibility factors between fracture segments and the control volumes; and
produce output values corresponding to the determined transmissibility factors for generation of a simulation of the subterranean region.
